(19) United States
(12) Patent Application Publication
(10) Pub. No.: US 2014/0261183 A1
(43) Pub. Date: Sep. 18, 2014

(54) COATING APPARATUS

(71) Applicants: NURI TECH CO., LTD., Incheon (KR); Samsung Display Co., Ltd., Yongin-City (KR)

(72) Inventors: JAE CHEOL PARK, Hwaseong-si (KR); Chunghyuk Lee, Yongin-si (KR); Daeho Song, Hwaseong-si (KR); Nakcho Choi, Hwaseong-si (KR); Gyeongeun Eoh, Seoul (KR); Minjeong Oh, Incheon (KR); Min-Woo Lee, Seoul (KR); Sangkyun Bae, Incheon (KR)

(21) Appl. No.: 13/941,860

(22) Filed: Jul. 15, 2013

(30) Foreign Application Priority Data
Mar. 15, 2013 (KR) 10-2013-0027933

(51) Int. Cl. C23C 14/54

(52) U.S. Cl. CPC C23C 14/542
USPC 118/724; 118/722

(57) ABSTRACT

A coating apparatus including an evaporation part, a thermal decomposition part, a deposition chamber, a vacuum pump, and a discharge pipe. The deposition chamber includes an upper portion, a lower portion facing the upper portion, and a sidewall portion connecting the upper portion and the lower portion to each other and including an inlet, first outlet, a second outlet, a third outlet and a fourth outlet. The discharge pipe includes a first auxiliary pipe connected to the first outlet and the second outlet, a second auxiliary pipe connected to the third outlet and the fourth outlet, an intermediate pipe connected to the first auxiliary pipe and the second auxiliary pipe, and a main pipe connected to the intermediate pipe. The vacuum pump is configured to discharge a portion of the monomer of the deposition material, which is not deposited, from the deposition chamber through the discharge pipe.

### CROSS-REFERENCE TO RELATED APPLICATION

This application claims priority to Korean Patent Application No. 10-2013-0027933, filed on Mar. 15, 2013, the disclosure of which is hereby incorporated by reference herein in its entirety.

### 1. TECHNICAL FIELD

Exemplary embodiments of the present invention relate to a coating apparatus. More particularly, exemplary embodiments of the present invention relate to a parylene coating apparatus.

### 2. DISCUSSION OF THE RELATED ART

In general, manufactures, such as, for example, a printed circuit board, medical equipment, a display panel, etc., include a protective layer to increase a corrosion resistance, a damp-proof property, an oxidation prevention property, etc of the manufactures. The protective layer may serve as an outermost layer of the manufactures.

The protective layer may have different thicknesses according to areas thereof. The difference of the thickness of the protective layer may cause a weakness with respect to the protective layer. For example, corrosion and oxidation may occur in the areas of the manufactures, in which the thickness of the protective layer is relatively thin.

### SUMMARY

Exemplary embodiments of the present invention provide a coating apparatus capable of forming a uniform protective layer.

Exemplary embodiments of the present invention provide a coating apparatus including an evaporation part, a thermal decomposition part, a deposition chamber, a vacuum pump, and a discharge pipe. The evaporation part is configured to evaporate a dimer of a deposition material, and the thermal decomposition part is configured to thermally decompose the dimer of the evaporated deposition material to a monomer.

The deposition chamber includes an upper portion, a lower portion facing the upper portion, and a sidewall portion connecting the upper portion and the lower portion to each other. A plurality of subjects configured to receive w the monomer of the deposition material thereon is disposed on the lower portion, and the sidewall portion includes an inlet and a first outlet, a second outlet, a third outlet, and a fourth outlet disposed between the lower portion and the upper portion.

The discharge pipe includes a first auxiliary pipe connected to the first outlet and the second outlet, a second auxiliary pipe connected to the third outlet and the fourth outlet, an intermediate pipe connected to the first auxiliary pipe and the second auxiliary pipe, and a main pipe connected to the intermediate pipe. The vacuum pump is configured to provide a fluid path for the deposition material between the evaporation part and the discharge pipe and configured to discharge a portion of the monomer of the deposition material, which is not deposited, from the deposition chamber through the discharge pipe.

The subjects are substantially in parallel with the lower portion and spaced apart from each other at regular intervals between the lower portion and the upper portion.

The subjects are supported by a plurality of supporters, respectively. Cooling devices are respectively disposed at the supporters to control a deposition temperature around the supporters.

The inlet faces the first outlet, the second outlet, the third outlet, and the fourth outlet. A diffusion plate is disposed inside the deposition chamber facing the inlet, and the diffusion plate includes a curved portion facing the inlet.

The intermediate pipe has a cross-sectional area greater than a cross-sectional area of the first auxiliary pipe and a cross-sectional area of the second auxiliary pipe, and the main pipe has a cross-sectional area greater than the cross-sectional area of the intermediate pipe. Each of the first auxiliary pipe, the second auxiliary pipe, and the intermediate pipe is formed in a curved shape and has at least one bending portion.

According to an exemplary embodiment of the present invention, a coating apparatus is provided. The coating apparatus includes a raw material supply part, an evaporation part configured to evaporate a dimer of a deposition material supplied in powder form thereto by the raw material supply part, and in which the raw material supply part is connected to the evaporation part by a first pipe connection, a thermal decomposition part connected to the evaporation part through a second connection pipe and configured to thermally decompose the dimer of the evaporated deposition material to a monomer, a deposition chamber connected to the thermal decomposition part by a third connection pipe. The deposition chamber includes a lower portion, an upper portion facing the lower portion, a sidewall portion connecting the lower portion and the upper portion to each other, and a stage disposed on the lower portion and including a plurality of supporters fixed thereto which are configured to support a plurality of respective subjects which are configured to receive the monomer of the deposition material thereon, a plurality of cooling devices provided to the supporters and which are configured to lower a temperature around the supporters, and a heating device disposed at the sidewall portion of the deposition chamber. The sidewall portion includes an inlet, a first outlet, a second outlet, a third outlet, and a fourth outlet disposed between the lower portion and the upper portion.

In addition, the coating apparatus further includes an air cooling device disposed on an outer surface of the evaporation part and is configured to cool the evaporation part and includes a plurality of discharge holes therein, a fourth connection pipe that includes a first auxiliary pipe connected to the first outlet and the second outlet, a second auxiliary pipe connected to the third outlet and the fourth outlet, an intermediate pipe connected to the first auxiliary pipe and the second auxiliary pipe, and a main pipe connected to the intermediate pipe, a cold trap configured to refrigerate the monomer of the evaporated deposition material discharged from the deposition chamber and is connected to deposition chamber by the main pipe of the fourth connection pipe, and a vacuum pump connected to the cold trap through a fifth connection pipe. The vacuum pump is configured to discharge a portion of the monomer of the deposition material, which is not deposited, from the deposition chamber through the fourth connection pipe and is configured to generate a fluid path for the deposition material between the evaporation part and the discharge pipe by discharging the portion of the monomer of the deposition material.

Also, the coating apparatus further includes a control part operatively connected to each of the raw material supply part, the thermal decomposition part, the evaporation part and the vacuum pump. The control part is configured to control a temperature of the evaporation part and the thermal decomposition part and is configured to control the supply of the dimer from the raw material supply part. Moreover, the control part is configured to control a suction intensity of the vacuum pump. According to the above, the discharge pipe forms uniform discharge paths regardless of areas of the deposition chamber. Due to the coating apparatus, the protective layer is uniformly formed on the subjects regardless of the position of the subjects.

The cooling device disposed on the stage prevents the subjects from being heated and controls the temperature around the stage to increase a deposition efficiency of the parylene monomer. The cooling device disposed on the deposition chamber prevents the parylene monomer from being deposited on the inner sidewall of the deposition chamber.

The diffusion plate diffuses the parylene monomer to the whole space of the deposition chamber, which is entered through the inlet of the deposition chamber.

### BRIEF DESCRIPTION OF THE DRAWINGS

Exemplary embodiments of the present invention can be understood in more detail from the following detailed description when considered in conjunction with the accompanying drawings in which:

FIG. 1 is a block diagram showing a coating apparatus according to an exemplary embodiment of the present invention;

FIG. 2 is a perspective view showing a deposition chamber and a discharge pipe according to an exemplary embodiment of the present invention;

FIG. 3 is a view showing a fluid path of the deposition chamber shown in FIG. 2;

FIG. 4 is a partially cut-away perspective view of the deposition chamber shown in FIG. 2;

FIG. 5 is a perspective view showing a subject for deposition shown in FIG. 4;

FIG. 6 is a view showing a discharge pipe according to an exemplary embodiment of the present invention;

FIGS. 7A to 7C are views showing an inlet area of a deposition chamber according to an exemplary embodiment of the present invention;

FIGS. 8A and 8B are views showing a diffusion plate according to an exemplary embodiment of the present invention; and

FIG. 9 is a perspective view showing an evaporation part according to an exemplary embodiment of the present invention.

### DETAILED DESCRIPTION OF EXEMPLARY EMBODIMENTS

It will be understood that when an element or layer is referred to as being “on”, “connected to” or “coupled to” another element or layer, it can be directly on, connected or coupled to the other element or layer or intervening elements or layers may be present. Like numbers refer to like elements throughout. As used herein, the term “and/or” includes any and all combinations of one or more of the associated listed items.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, exemplary embodiments of the present invention will be explained in detail with reference to the accompanying drawings.

FIG. 1 is a block diagram showing a coating apparatus according to an exemplary embodiment of the present invention.

Referring to FIG. 1, the coating apparatus includes, for example, a raw material supply part 100, an evaporation part 200, a thermal decomposition part 300, a deposition chamber 400, a cold trap 500, a vacuum pump 600, and a control part 700.

The raw material supply part 100 supplies a dimer in a powder form of a deposition material to the evaporation part 200. In the present exemplary embodiment, the deposition material may be, but is not limited to, Parylene. That is, various materials may be used as the deposition material as long as the evaporated dimer is thermally decomposed to a monomer.

The raw material supply part 100 and the evaporation part 200 are connected to each other by, for example, a first connection pipe FP1. The raw material supply part 100 supplies, for example, a parylene dimer to the evaporation part 200 in a uniform amount. The supply amount of the parylene dimer is controlled by, for example, calculating a mass variation amount of the parylene dimer contained in the raw material supply part 100.

The evaporation part 200 evaporates the parylene dimer supplied thereto. The evaporation part 200 heats the parylene dimer at, for example, a temperature of about 150 degrees to about 230 degrees. The evaporation part 200 and the thermal decomposition part 300 are connected to each other by, for example, a second connection pipe FP2. The evaporation part 200 provides the evaporated parylene dimer to the thermal decomposition part 300 through the second connection pipe FP2.

The thermal decomposition part 300 thermally decomposes the evaporated parylene dimer to the parylene monomer. For the thermal decomposition reaction, the thermal decomposition part 300 heats the evaporated parylene dimer at, for example, about 650 degrees. The parylene dimer may be, for example, di-para-xylene, monochloro-para-xylene, or dichloro-para-xylene.

The thermal decomposition part 300 and the deposition chamber 400 are connected to each other by, for example, a third connection pipe FP3. The thermal decomposition part 300 provides the parylene monomer to the deposition chamber 400 through the third connection pipe FP3.

The deposition chamber 400 accommodates at least one subject for deposition. The parylene monomer is deposited on the subject to form a polymer. The polymer serves as a protective layer to protect the subject. The subject may be, but is not limited to, a display panel.

The deposition chamber 400 and the cold trap 500 are connected to each other by, for example, a fourth connection pipe FP4. The parylene monomer, which is not deposited on the subject, is discharged from the deposition chamber 400 through the fourth connection pipe FP4.

The cold trap 500 refrigerates the parylene monomer, which is not deposited on the subject. The refrigerated parylene monomer does not flow backward toward the deposition chamber 400. The cold trap 500 and the vacuum pump 600 are connected to each other by, for example, a fifth connection pipe FP5. Alternatively, in an exemplary embodiment, the cold trap 500 may be omitted. In this case, the deposition chamber 400 and the vacuum pump 600 are, for example, directly connected to each other by the fourth connection pipe FP4.

A fluid path for the parylene monomer is formed by, for example, suction of the vacuum pump 600, and a velocity of the parylene monomer is determined by a suction intensity of the vacuum pump 600.

The control part 700 controls the coating apparatus. The control part 700 controls the supply amount of the parylene dimer from the raw material supply part 100. In addition, the control part 700 controls the temperature of the evaporation part 200 and the thermal decomposition part 300. Further, the control part 700 controls the suction intensity of the vacuum pump 600. Although not shown in FIG. 1, a valve may be installed at each of the first to fifth connection pipes FP1 to FP5 to control the amount of the fluid flowing through a corresponding connection pipe of the first to fifth connection pipes FP1 to FP5.

FIG. 2 is a perspective view showing a deposition chamber and a discharge pipe according to an exemplary embodiment of the present disclosure and FIG. 3 is a view showing a fluid path of the deposition chamber shown in FIG. 2.

Referring to FIG. 2, the deposition chamber 400 includes, for example, a lower portion 410, an upper portion 420, and a sidewall portion 430 that connects the lower portion 410 and the upper portion 420. The deposition chamber 400 may have, for example, a cylinder shape as shown in FIG. 2, but exemplary embodiments of the present invention are not limited to this particular shape for the deposition chamber 400. Rather, the deposition chamber 400 may be formed in various shapes.

The subjects include, for example, SUB1, SUB2, SUB3, SUB4, SUB5, SUB6, SUB7, SUB8, SUB9 and SUB10, on which the parylene monomer is deposited. The subjects SUB1 to SUB10 are disposed on the lower portion 410. FIG. 2 shows ten subjects SUB1 to SUB10 each having a plate shape, but exemplary embodiments of the present invention are not limited to this particular shape for the ten subjects SUB1 to SUB10. Rather, the tens subjects SUB1 to SUB10 may be formed in various shapes.

The subjects SUB1 to SUB10 are disposed on the lower portion 410 to be, for example, substantially in parallel to each other. The subjects SUB1 to SUB10 are, for example, spaced apart from each other at regular intervals between the lower portion 410 and the upper portion 420.

The deposition chamber 400 includes, for example, an inlet 430-I, a first outlet 430-O1, a second outlet 430-O2, a third outlet 430-O3, and a fourth outlet 430-O4, which are formed through the sidewall portion 430. The first outlet 430-O1, the second outlet 430-O2, the third outlet 430-O3, and the fourth outlet 430-O4 are, for example, spaced apart from each other at regular intervals between the lower portion 410 and the upper portion 420.

For example, a distance ID1 between the first outlet 430-O1 and the second outlet 430-O2, a distance ID2 between the second outlet 430-O2 and the third outlet 430-O3, and a distance ID3 between the third outlet 430-O3 and the fourth outlet 430-O4 are equal to each other. Here, a direction in which the first outlet 430-O1, the second outlet 430-O2, the third outlet 430-O3, and the fourth outlet 430-O4 are arranged is referred to, for example, as a first direction DR1. The first direction DR1 corresponds to a normal line direction of the lower portion 410. The lower portion 410 is parallel to a plane defined by a second direction DR2 and a third direction DR3. The inlet 430-I is disposed, for example, to face the first outlet 430-O1, the second outlet 430-O2, the third outlet 430-O3, and the fourth outlet 430-O4. Thus, the fluid path between the inlet 430-I and the first to fourth outlets 430-O1 to 430-O4 becomes longer, so that a deposition probability of the parylene monomer on the subjects SUB1 to SUB10 become higher.

The portion of the parylene monomer, which is not deposited on the subjects SUB1 to SUB10, is discharged through the fourth connection pipe FP4 from the deposition chamber 400. The fourth connection pipe FP4 serves as the discharge pipe of the deposition chamber 400. The term fourth connection pipe and discharge pipe are referred to interchangeably with the same reference numeral “FP4” herein.

The discharge pipe FP4 includes, for example, a first auxiliary pipe FP4-1, a second auxiliary pipe FP4-2, an intermediate pipe FP4-3, and a main pipe FP4-4. The first auxiliary pipe FP4-1 is connected to, for example, the first outlet 430-O1 and the second outlet 430-O2, and the second auxiliary pipe FP4-2 is connected to the third outlet 430-O3 and the fourth outlet 430-O4.

For example, the intermediate pipe FP4-3 is connected to the first auxiliary pipe FP4-1 and the second auxiliary pipe FP4-2, and the main pipe FP4-4 is connected to the intermediate pipe FP4-3 and the cold trap 500 (refer to FIG. 1).

Referring to FIG. 3, the first auxiliary pipe FP4-1 provides one intermediate discharge path from the first outlet 430-O1 and the second outlet 430-O2, and the second auxiliary pipe FP4-2 provides the other one intermediate discharge path from the third outlet 430-O3 and the fourth outlet 430-O4. The intermediate pipe FP4-3 provides a main discharge path from the first auxiliary pipe FP4-1 and the second auxiliary pipe FP4-2.

Due to the discharge pipe FP4, fluid paths are uniformly formed between the inlet 430-I and the first to fourth outlets 430-O1 to 430-O4 regardless of areas of the deposition chamber 400. Accordingly, the protective layer may be uniformly formed on the subjects SUB1 to SUB10 regardless of the position of the subjects SUB1 to SUB10.

FIG. 4 is a partially cut-away perspective view of the deposition chamber shown in FIG. 2.

Referring to FIG. 4, a stage ST is disposed in the deposition chamber 400. The stage ST includes, for example, supporters SS7, SS8, SS9 and SS10 and fixing axes SPT to fix the supporters SS7 to SS10 thereto. FIG. 4 shows four supporters SS7 to SS10 among ten supporters and four subjects SUB7 to SUB10 respectively corresponding to the four supporters SS7 to SS10.

The supporters SS7 to SS10 are, for example, spaced apart from each other at regular intervals in the first direction DR1. The supporters SS7 to SS10 support, for example, the subjects SUB7 to SUB10, respectively. Cooling devices CA7, CA8, CA9 and CA10 are, for example, respectively provided to the supporters SS7 to SS10. Each of the cooling devices CA7 to CA10 is, for example, attached to a lower surface of a corresponding supporter of the supporters SS7 to SS10. Each of the cooling devices CA7 to CA10 may be, but are not limited to, a pipe through which a coolant gas or water is circulated. Alternatively, in an exemplary embodiment, the cooling devices CA7 to CA10 may be, for example, disposed inside the supporters SS7 to SS10, respectively.

The cooling devices CA7 to CA10 lower the temperature around the supporters SS7 to SS10, which, for example, is lower than the temperature in other areas. For example, the parylene monomer has a high deposition efficiency at a temperature of about 30 degrees, but the parylene monomer entered into the deposition chamber 400 right after being thermally decomposed has a temperature higher than about 30 degrees. The cooling devices CA7 to CA10 lower the temperature around the supporters SS7 to SS10 to, for example, indirectly lower the temperature of the parylene monomer deposited on the subjects SUB1 to SUB10. Thus, the deposition efficiency of the parylene monomer may be increased.

A heating device HA is, for example, disposed at the sidewall portion 430 of the deposition chamber 400. The heating device HA is configured to include, for example, a heating cable disposed on an inner side surface or a pipe through which a liquid at a high temperature is circulated. The heating device HA heats the sidewall portion 430 to prevent the parylene monomer from being deposited on the inner side surface of the sidewall portion.

FIG. 5 is a perspective view showing the subject for deposition shown in FIG. 4, and a display panel has been shown in FIG. 5 as a representative example.

Referring to FIG. 5, the display panel DP includes, for example, a base substrate BS on which a plurality of pixel areas PXA are defined. For example, the base substrate BS may be formed of a transparent material such, as glass, quartz or plastic. First electrodes EL1 are disposed on the base substrate BS to respectively correspond to the pixel areas PXA. Second electrodes EL2 each having, for example, a tunnel are disposed on the base substrate BS to respectively correspond to the pixel areas PXA.

Liquid crystal molecules LC are disposed in the tunnels, and an arrangement of the liquid crystal molecules LC in the tunnels is changed by an electric field formed by the first and second electrodes EL1 and EL2 disposed in each pixel area PXA.

The parylene protective layer is formed on the display panel DP in the deposition chamber 400 to cover the second electrodes EL2. The parylene protective layer seals openings of the tunnels.

Although not shown in figures, the base substrate BS may further include, for example, wirings and switching devices to apply signals to the first electrodes EL1. In addition, the display panel DP may further include, for example, an organic/inorganic layer formed on the second electrodes EL2 before the parylene protective layer is formed. Different from the subject shown in FIG. 5, the tunnels may be formed by, for example, the organic/inorganic layer. In this case, the second electrodes EL2 are, for example, disposed on the tunnels to face the first electrodes EL1.

FIG. 6 is a view showing the discharge pipe according to an exemplary embodiment of the present invention. The same reference numerals denote the same elements in FIG. 2, and thus detailed descriptions of the same elements will be omitted.

Referring to FIG. 6, a discharge pipe FP40 includes, for example, a first auxiliary pipe FP40-1, a second auxiliary pipe FP40-2, an intermediate pipe FP40-3, and a main pipe FP40-4.

For example, as shown in FIG. 6, the intermediate pipe FP40-3 has a diameter DM3 greater than a diameter DM1 of the first auxiliary pipe FP40-1 and a diameter DM2 of the second auxiliary pipe FP40-2. The main pipe FP40-4 has, for example, a diameter DM4 greater than a diameter DM3 of the intermediate pipe FP40-3. In other words, a cross-sectional area of the intermediate pipe FP40-3 is greater than a cross-sectional area of the first auxiliary pipe FP40-1 and a cross-sectional area of the second auxiliary pipe FP40-2, and a cross-sectional area of the main pipe FP40-4 is greater than a cross-sectional area of the intermediate pipe FP40-3.

Although the parylene monomer flowing through the first auxiliary pipe FP40-1 and the second auxiliary pipe FP40-2 enters into the intermediate pipe FP40-3, the velocity of the parylene monomer is not reduced. In addition, although the parylene monomer flowing through the intermediate pipe FP40-3 enters into the main pipe FP40-4, the velocity of the parylene monomer is not decreased. Therefore, the parylene monomer, which is not deposited on the subjects, is smoothly discharged from the deposition chamber 400 through the discharge pipe FP40.

Each of the first auxiliary pipe FP40-1, the second auxiliary pipe FP40-2, and the intermediate pipe FP40-3 includes, for example, at least one bending portion VP. Each of the first auxiliary pipe FP40-1, the second auxiliary pipe FP40-2, and the intermediate pipe FP40-3 is, for example, bent at the bending portion VP to have a curved shape. In FIG. 6, each of the first auxiliary pipe FP40-1, the second auxiliary pipe FP40-2, and the intermediate pipe FP40-3 includes, for example, two bending portions VP, and thus each of the first auxiliary pipe FP40-1, the second auxiliary pipe FP40-2, and the intermediate pipe FP40-3 has, for example, a U shape. Due to curved shape of the bending portion VP, the decrease of the velocity of the parylene monomer is minimized and a pressure applied to the bending portion VP is lowered.

The discharge pipe FP40 further includes, for example, a born-type connection pipe BP disposed between end portions of the first auxiliary pipe FP40-1 and the first and second outlets 430-O1 and 430-O2 (refer to FIG. 2). The horn-type connection pipe BP has, for example, a cross-sectional area gradually increased as it is closer to the first outlet 430-O1 from the end portions of the first auxiliary pipe FP40-1. The horn-type connection pipe BP is disposed, for example, between end portions of the second auxiliary pipe FP40-2 and the third and fourth outlets 430-O3 and 430-O4. The horn-type connection pipe BP, for example, increases the amount of the parylene monomer entered into the discharge pipe FP40, which is not deposited on the subjects.

FIGS. 7A to 7C are views showing an inlet area of the deposition chamber according to an exemplary embodiment of the present invention, and FIGS. 8A and 8B are views showing a diffusion plate according to an exemplary embodiment of the present invention.

Referring to FIGS. 7A to 7C, the deposition chamber 400 includes, for example, an inlet area 430-IA protruded from the sidewall portion 430. The inlet 430-I is formed, for example, through the inlet area 430-IA. The inlet 430-I is connected to the third connection pipe FP3.

A diffusion plate DS is disposed, for example, inside the deposition chamber 400 to face the inlet 430-I. The parylene monomer entered into the inlet 430-I, for example, collides with the diffusion plate DS and are uniformly distributed. The diffusion plate DS is formed of, for example, stainless steel.

Referring to FIGS. 8A and 8B, the diffusion plate DS includes, for example, a curved surface CS facing the inlet 430-I. As shown in FIGS. 8A and 8B, the diffusion plate DS is totally curved.

The diffusion plate DS includes, for example, an upper portion UP, a center portion CP, and a lower portion LP, which are arranged in the first direction DR1. For example, a width W10 of the center portion CP in the second direction DR2 substantially perpendicular to the first direction DR1 is greater than widths W20 and W30 of the upper and lower portions UP and LP in the second direction DR2. In addition, the widths W20 and W30 of the upper and lower portions UP and LP in the second direction DR2 are, for example, gradually decreased as they are further away from the center portion CP.

The upper portion UP, the center portion CP, and the lower portion LP have, for example, substantially the same length in the first direction DR1. The center portion CP has, for example, a hexagon shape and the upper and lower portions UP and LP have, for example, an isosceles trapezoid shape.

The center portion CP facing the inlet 430-I prevents the parylene monomer from being directly provided to a portion of the subjects SUB1 to SUB10. The upper and lower portions UP and LP increase the amount of the parylene monomer diffused to the upper and lower sides of the deposition chamber 400.

FIG. 9 is a perspective view showing an evaporation part according to an exemplary embodiment of the present invention.

The evaporation part 200 has, for example, a pipe shape, and a heating cable (not shown) is disposed in the evaporation part 200. The evaporated amount of the parylene dimer is changed depending on the temperature.

An air-cooling device ACA is disposed on an outer surface of the evaporation part 200 to cool the evaporation part 200. The air-cooling device ACA surrounds the evaporation part 200. The air-cooling device ACA has, for example, a tube shape with discharge holes OH through which a gas is discharged, e.g., air or nitrogen gas. The air-cooling device ACA is not limited to the tube shape mentioned above but rather may be formed in various shapes. The gas discharged through the discharge holes OH cools the evaporation part 200.

The air-cooling device ACA is operated when the deposition process performed in the deposition chamber 400 is finished. After the process of depositing the parylene monomer is completed, the evaporation part 200 is rapidly cooled by the air-cooling device ACA, and thus the evaporation of the parylene monomer is stopped. Therefore, the parylene monomer or the parylene dimer, which is not necessary, may be prevented from entering into the deposition chamber 400.

Having described the exemplary embodiments of the present invention, it is further noted that it is readily apparent to those of ordinary skill in the art various modifications may be made without departing from the spirit and scope of the invention which is defined by the metes and bounds of the appended claims.

What is claimed is:

1. A coating apparatus comprising:
an evaporation part configured to evaporate a dimer of a deposition material;
a thermal decomposition part configured to thermally decompose the dimer of the evaporated deposition material to a monomer;
a deposition chamber that includes a lower portion on which a plurality of subjects configured to receive the monomer of the deposition material thereon is disposed, an upper portion facing the lower portion, and a sidewall portion connecting the lower portion and the upper portion to each other and including an inlet, a first outlet, a second outlet, a third outlet, and a fourth outlet, wherein the first outlet, the second outlet, the third outlet, and the fourth outlet are disposed between the lower portion and the upper portion;
a discharge pipe that includes a first auxiliary pipe connected to the first outlet and the second outlet, a second auxiliary pipe connected to the third outlet and the fourth outlet, an intermediate pipe connected to the first auxiliary pipe and the second auxiliary pipe, and a main pipe connected to the intermediate pipe; and
a vacuum pump configured to discharge a portion of the monomer of the deposition material, which is not deposited, from the deposition chamber through the discharge pipe and configured to generate a fluid path for the deposition material between the evaporation part and the discharge pipe by discharging the portion of the monomer of the deposition material.

2. The coating apparatus of claim 1, wherein the first outlet, the second outlet, the third outlet, and the fourth outlet are spaced apart from each other at regular intervals.

3. The coating apparatus of claim 1, wherein the subjects are substantially in parallel with the lower portion and spaced apart from each other at regular intervals between the lower portion and the upper portion.

4. The coating apparatus of claim 3, further comprising a stage that includes a plurality of supporters disposed inside the deposition chamber which are configured to support the subjects and configured to fix axes to fix the supporters thereto.

5. The coating apparatus of claim 4, further comprising a plurality of cooling devices respectively disposed at the supporters to control a deposition temperature around the supporters.

6. The coating apparatus of claim 3, wherein the inlet faces the first outlet, the second outlet, the third outlet, and the fourth outlet.

7. The coating apparatus of claim 6, further comprising a diffusion plate disposed inside the deposition chamber facing the inlet.

8. The coating apparatus of claim 7, wherein the diffusion plate comprises a curved portion facing the inlet.

9. The coating apparatus of claim 8, wherein a direction in which the first outlet, the second outlet, the third outlet, and the fourth outlet are disposed is defined as a first direction, a direction substantially perpendicular to the first direction is defined as a second direction, wherein the diffusion plate is divided into an upper portion, a center portion, and a lower portion disposed in the first direction, a width in the second direction of the center portion is greater than widths in the second direction of the upper and lower portions, and wherein the widths of the upper and lower portions decrease as the upper and lower portions are further away from the center portion.

10. The coating apparatus of claim 1, wherein the intermediate pipe has a cross-sectional area greater than a cross-sectional area of the first auxiliary pipe and a cross-sectional area of the second auxiliary pipe, and the main pipe has a cross-sectional area greater than the cross-sectional area of the intermediate pipe.

11. The coating apparatus of claim 10, wherein each of the first auxiliary pipe, the second auxiliary pipe, and the intermediate pipe has a curved shape and has at least one bending portion.

12. The coating apparatus of claim 10, further comprising a horn-type connection pipe disposed between an end portion of the first auxiliary pipe and the first outlet and has a cross-sectional area gradually increasing as the horn-type connection pipe is closer to the first outlet.

13. The coating apparatus of claim 1, wherein the deposition material comprises a parylene.

14. The coating apparatus of claim 1, further comprising a raw material supply part configured to supply the dimer of the deposition material to the evaporation part, wherein the dimer of the deposition material is in a powder form.

15. The coating apparatus of claim 1, further comprising an air-cooling device that surrounds the evaporation part to reduce a temperature of the evaporation part.

16. The coating apparatus of claim 1, further comprising a heating device disposed at the sidewall portion of the deposition chamber.

17. The coating apparatus of claim 1, further comprising a cold trap configured to refrigerate the monomer of the evaporated deposition material discharged from the deposition chamber.

18. The coating apparatus of claim 9, wherein the center portion of the diffusion plate has a hexagon shape and the upper portion and the lower portion of the diffusion plate have an isosceles trapezoid shape.

19. A coating apparatus comprising:
a raw material supply part;
an evaporation part configured to evaporate a dimer of a deposition material supplied in powder form thereto by the raw material supply part, wherein the raw material supply part is connected to the evaporation part by a first pipe connection;
a thermal decomposition part connected to the evaporation part through a second connection pipe and configured to thermally decompose the dimer of the evaporated deposition material to a monomer;
a deposition chamber connected to the thermal decomposition part by a third connection pipe, wherein the deposition chamber includes a lower portion, an upper portion facing the lower portion, a sidewall portion connecting the lower portion and the upper portion to each other, and a stage disposed on the lower portion and including a plurality of supporters fixed thereto which are configured to support a plurality of respective subjects which are configured to receive the monomer of the deposition material thereon, a plurality of cooling devices provided to the supporters and which are configured to lower a temperature around the supporters, and a heating device disposed at the sidewall portion of the deposition chamber, wherein the sidewall portion includes an inlet, a first outlet, a second outlet, a third outlet, and a fourth outlet disposed between the lower portion and the upper portion and wherein the first outlet, the second outlet, the third outlet, and the fourth outlet are disposed between the lower portion and the upper portion;
an air cooling device disposed on an outer surface of the evaporation part and configured to cool the evaporation part, wherein the air cooling device includes a plurality of discharge holes therein;
a fourth connection pipe that includes a first auxiliary pipe connected to the first outlet and the second outlet, a second auxiliary pipe connected to the third outlet and the fourth outlet, an intermediate pipe connected to the first auxiliary pipe and the second auxiliary pipe, and a main pipe connected to the intermediate pipe;
a cold trap configured to refrigerate the monomer of the evaporated deposition material discharged from the deposition chamber, wherein the cold trap is connected to deposition chamber by the main pipe of the fourth connection pipe;
a vacuum pump connected to the cold trap through a fifth connection pipe and wherein the vacuum pump is configured to discharge a portion of the monomer of the deposition material, which is not deposited, from the deposition chamber through the fourth connection pipe and configured to generate a fluid path for the deposition material between the evaporation part and the discharge pipe by discharging the portion of the monomer of the deposition material;
a control part operatively connected to each of the raw material supply part, the thermal decomposition part, the evaporation part and the vacuum pump, wherein the control part is configured to control a temperature of the evaporation part and the thermal decomposition part, wherein the control part is configured to control the supply of the dimer from the raw material supply part, and wherein the control part is configured to control a suction intensity of the vacuum pump.

20. The coating apparatus of claim 19, wherein the dimer is a parylene dimer.
